(19) United States
(12) Patent Application Publication
(10) Pub. No.: US 2025/0203783 A1
(43) Pub. Date: Jun. 19, 2025

(54) REPAIR USING COMBINED 2D AND 3D

(71) Applicant: Orbotech Ltd., Yavne (IL)

(72) Inventor: Oded Mor, Shoham (IL)

(21) Appl. No.: 18/734,631

(22) Filed: Jun. 5, 2024

Related U.S. Application Data
(60) Provisional application No. 63/611,771, filed on Dec. 19, 2023.

(51) Int. Cl. H05K 3/22; B23K 26/03; B23K 26/082; B23K 26/16; B23K 26/40

(52) U.S. Cl. CPC H05K 3/225; B23K 26/032; B23K 26/082; B23K 26/16; B23K 26/40

(57) ABSTRACT

A repair system may use a laser to repair defects, such as excess material defects and open defects. The repair system may use a method of repairing the defect which combines 2D images and a 3D measurement during the repair. Combining the 2D images and the 3D measurement during the repair may reduce the repair time for defects while repairing the finest portions of the defects.

### CROSS REFERENCE TO RELATED APPLICATION

The present application claims the benefit under 35 U.S.C. § 119 (e) of U.S. Provisional Application Ser. No. 63/611,771, filed Dec. 19, 2023, titled “REPAIR USING COMBINED 2D AND 3D”, which is incorporated herein by reference in the entirety.

### TECHNICAL FIELD

The present disclosure generally relates to printed circuits, and more particularly to repairing printed circuits.

### BACKGROUND

Printed circuits may include defects during manufacturing, such as excess material defects (e.g., short defects) or missing material defects (e.g., open defects). Printed circuits with defects are either discarded or repaired. Repairing the defects is desirable to improve yield and reduce scrap. Therefore, it would be advantageous to provide a device, system, and method that cures the shortcomings described above.

### SUMMARY

A repair system is described, in accordance with one or more embodiments of the present disclosure. The repair system may include: a light source configured to generate illumination; a laser generator configured to generate laser light; a two-axis scanner configured to steer the laser light; a sample stage configured to support a sample; an objective lens, wherein the laser light is configured to pass through the objective lens to the sample to perform a repair of a defect located at a defect location on the sample; a detector configured to generate a 2D image of the defect location based on collected light, wherein the collected light reflects or is emitted from the defect location, through the objective lens, to the detector; and a controller including one or more processors configured to execute program instructions maintained on a memory, the program instructions causing the controller to: generate a 3D measurement of the defect location; determine a 3D shape of the defect by comparing the 3D measurement with an expected design of the defect location; ablate the 3D shape of the defect by iteratively: ablating a defect shape of the defect in a current layer by scanning the laser light at the defect shape; find a residue of the defect in the 2D image; and ablate the residue of the defect.

In some aspects, the 3D measurement is generated using depth from focus.

In some aspects, the detector is configured to generate a plurality of 2D images with a plurality of inter-image shifts in a focal plane; wherein the 3D measurement is generated from the plurality of 2D images.

In some aspects, the plurality of inter-image shifts in the focal plane may decrease towards a substrate of the sample.

In some aspects, the repair system may include a 3D camera; wherein the controller is configured to cause the 3D camera to generate the 3D measurement.

In some aspects, the program instructions cause the controller to segment the 3D shape into a plurality of defect shapes which are stacked together.

In some aspects, the program instructions cause the controller to determine the 3D shape has been ablated using an open loop condition.

In some aspects, the open loop condition is a depth ablated at the current layer estimated by the controller using a fluence of the laser light.

In some aspects, the repair system ablates the 3D shape without generating an additional 3D measurement.

In some aspects, the residue of the defect is below a 3D accuracy limit of the 3D measurement.

In some aspects, the program instructions cause the controller to iteratively generate the 2D image of the defect location, find the residue of the defect, and ablate the residue of the defect.

In some aspects, the program instructions cause the controller to iteratively generate the 2D image of the defect location, find the residue of the defect, and ablate the residue of the defect until the controller determines the residue of the defect is below an allowable defect size.

In some aspects, the program instructions cause the controller to refocus the laser light at a different depth when iteratively generating the 2D image of the defect location, finding the residue of the defect, and ablating the residue of the defect.

In some aspects, the defect is an excess material defect; wherein the laser light repairs the excess material defect by ablating the excess material defect.

In some aspects, the memory maintains a design file and a defect report, wherein the design file includes the expected design.

In some aspects, the collected light reflecting from the sample includes light emitted by the sample following excitation by at least one of the illumination or the laser light.

In some aspects, the illumination is directed to the sample in a brightfield configuration; wherein the illumination and the laser light are configured to pass through the objective lens to the sample.

In some aspects, the illumination is directed to the sample in a darkfield configuration.

In some aspects, the controller is configured to ablate the 3D shape of the defect by iteratively: ablating the defect shape of the defect in the current layer by scanning the laser light at the defect shape; and refocusing the laser light down to a next layer.

In some aspects, the controller is configured to ablate the defect shape of the defect in the current layer by scanning the laser light at the defect shape one time before refocusing the laser light down to the next layer.

In some aspects, the controller is configured to ablate the defect shape of the defect in the current layer by scanning the laser light at the defect shape a plurality of times before refocusing the laser light down to the next layer.

In some aspects, the controller is configured to ablate the defect shape of the defect in the current layer by scanning the laser light at the defect shape a plurality of times without refocusing the laser light down to a next layer.

In some aspects, the controller is configured to: generate an additional 3D measurement of the defect location, wherein the additional 3D measurement indicates the defect remains at the defect location; determine the 3D shape of the defect from the additional 3D measurement; ablate the 3D shape of the defect.

A method is described, in accordance with one or more embodiments of the present disclosure. The method may include: generating a 3D measurement of the defect location; determining a 3D shape of the defect by comparing the 3D measurement with an expected design of the defect location; ablating the 3D shape of the defect by iteratively: ablating a defect shape of the defect in a current layer by scanning the laser light at the defect shape; generating a 2D image; finding a residue of the defect in the 2D image; and ablating the residue of the defect.

### BRIEF DESCRIPTION OF THE DRAWINGS

The numerous advantages of the disclosure may be better understood by those skilled in the art by reference to the accompanying figures in which:

FIG. 1 depicts a block diagram of a repair system, in accordance with one or more embodiments of the present disclosure.

FIG. 2 depicts a flow diagram of a method of repair using combined two-dimensional (2D) images and three-dimensional (3D) measurements, in accordance with one or more embodiments of the present disclosure.

FIG. 3A depicts a 2D image of a top of a sample at a defect location with a substrate, an excess material defect, and a pair of conductors, in accordance with one or more embodiments of the present disclosure.

FIG. 3B depicts a side view of a 3D measurement of the sample at the defect location, in accordance with one or more embodiments of the present disclosure.

FIG. 3C depicts a top view of defect shapes scanned during ablation cycles at the defect location, in accordance with one or more embodiments of the present disclosure.

FIG. 3D depicts a 2D image of the top of the sample at the defect location after scanning the defect shapes during the ablation cycles with an excess material defect remaining which is below a 3D accuracy limit, in accordance with one or more embodiments of the present disclosure.

FIG. 3E depicts a 2D image of the top of the sample at the defect location after scanning based on the previous 2D image, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

A repair system may use a laser to repair defects, such as excess material (“short”) defects and missing material (“open”) defects. The repair system may use a method of repairing the defect which combines 2D images and a 3D measurement during the repair. Combining the 2D images and the 3D measurement during the repair may reduce the repair time for defects while repairing the finest portions of the defects and eliminating thin residues.

U.S. Pat. No. 8,290,239, titled “Automatic repair of electric circuits”; U.S. Patent Publication Number 2006/0226865, titled “Automatic defect repair system”; Chinese Patent Publication Number 114521061, titled “Method and equipment for repairing short circuit of printed circuit board by using laser”; Chinese Patent Publication Number CN217412792U, titled “Laser processing system”; Chinese Patent Publication Number CN113231732A, titled “Laser processing system and control method thereof”; are each incorporated herein by reference in the entirety.

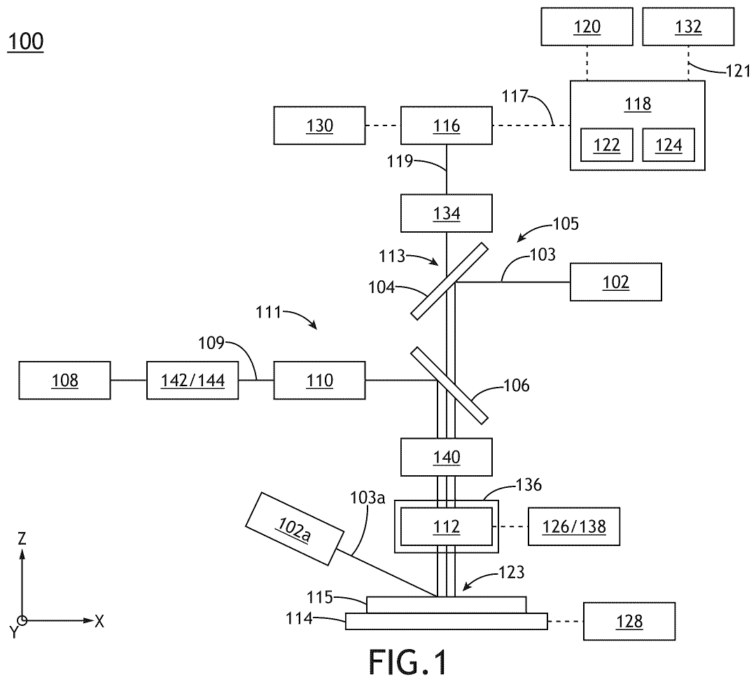

Referring now to FIG. 1, a repair system 100 is described, in accordance with one or more embodiments of the present disclosure. The repair system 100 may be a repair tool. The repair system 100 includes one or more components, such as, but not limited to, a light source 102 (e.g., an axial light source), light source 102a (e.g., a diffuse light source), beam splitter 104, beam splitter 106, laser generator 108, two-axis scanner 110 (such as a fast-steering mirror, a pair of Galvanometer scanners, two-axis acousto-optic deflectors, and the like), objective lens 112, sample stage 114, detector 116, controller 118, user interface 120, z-axis positioner 126, z-axis positioner 128, z-axis positioner 130, and the like.

In embodiments, the repair system 100 includes one or more sub-systems. The light source 102, the light source 102a, the beam splitter 104, the beam splitter 106, and the objective lens 112 may be an illumination sub-system. The laser generator 108, the two-axis scanner 110, the beam splitter 106, and the objective lens 112 may be a laser processing sub-system. The objective lens 112, the beam splitter 106, the beam splitter 104, and the detector 116 may be an image acquisition sub-system. The illumination sub-system, the laser processing sub-system, and the image acquisition sub-system may share a common optical path. For example, the illumination sub-system, the laser processing sub-system, and the image acquisition sub-system may include the objective lens 112 in common. By way of another example, the laser processing sub-system and the image acquisition sub-system may share the beam splitter 106 in common. The image acquisition sub-system and the laser processing sub-system may be combined, to reduce cost, volume, and repair time. In this regard, the repair system 100 may be considered an integrated repair and vision system.

The repair system 100 may include the light source 102. The light source 102 may be an illumination source. The light source 102 may generate illumination 103. The illumination 103 may include one or more selected wavelengths of light including, but not limited to, vacuum ultraviolet radiation (VUV), deep ultraviolet radiation (DUV), ultraviolet (UV) radiation, visible radiation, or infrared (IR) radiation. The illumination 103 may include any range of selected wavelengths. In embodiments, the light source 102 may include a spectrally-tunable illumination source to generate illumination 103 having a tunable spectrum. The illumination 103 includes one or more optical properties. For example, the optical properties of the illumination 103 may include, but are not limited to, an incidence angle, a collection angle of illumination reflected from the sample 115, one or more wavelengths, and the like.

The repair system 100 may include the beam splitter 104. The beam splitter 104 may be a beam combiner, a splitter/combiner, or the like. In embodiments, the light source 102 may direct the illumination 103 to the beam splitter 104 via an illumination path 105. The illumination 103 from the light source 102 may pass through the beam splitter 104. The illumination 103 may be on-axis after passing through the beam splitter 104. For example, the beam splitter 104 may combine the illumination 103 from the light source 102 such that the illumination 103 is on-axis with the detector 116 and/or the sample 115. The illumination 103 which is on-axis with the detector 116 and/or the sample 115 may be in brightfield configuration. In embodiments, the illumination 103 may be made parallel to the optical axis of the objective lens 112 by the beam splitter 104. The illumination 103 may be configured to pass through the objective lens 112 to the sample 115. The illumination 103 may be directed to the sample 115 in the brightfield configuration. The beam splitter 104 may be oriented such that the light source 102 may simultaneously direct the illumination 103 to the sample 115 and such that the detector may collect illumination reflected from the sample 115.

Although the repair system 100 is described as including the beam splitter 104 and the illumination 103 is described as on-axis or in the brightfield configuration, this is not intended as a limitation of the present disclosure. In embodiments, the repair system 100 may include a light source 102a. The discussion of the light source 102 is incorporated herein by reference as to the light source 102a. The light source 102a may generate illumination 103a. The illumination 103a may be off-axis. The illumination 103a may be directed to the sample 115 in a darkfield configuration. The repair system 100 may include the light source 102 which generates the illumination 103 and/or the light source 102a which generates the illumination 103a. Thus, the repair system 100 may include a brightfield configuration and/or a darkfield configuration.

The repair system 100 may include the laser generator 108. The laser generator 108 may generate laser light 109. The laser generator 108 may be a pulsed laser generator and the laser light 109 may be a pulsed beam.

The laser light 109 may include one or more optical properties. The optical properties may include optical properties of the laser light 109 and/or of the beam of the laser light 109 as manipulated by the various optical elements of the repair system 100 (e.g., the objective lens 112, etc.). For example, the optical properties of the laser light 109 may include a spot size, fluence, waist position, beam profile, wavelength, Rayleigh length, energy, defocus, diameter, and the like.

The laser light 109 may include a selected spot size. The spot size may also be a waist radius, spot area, a focal spot, wo, or the like. The objective lens 112 may focus the laser light 109 to the spot size. The spot size may be the minimum beam radius of the laser light 109. The spot size may be located at the waist position. The beam radius of the laser light 109 may increase away from the waist position.

The laser light 109 may include a selected fluence. The fluence may be dependent upon the spot size and the laser energy. For example, the fluence may be the laser energy per unit area of the spot size. The fluence may be highest at the waist position and may be reduced as the beam cross section increases away from waist position. At the waist position, the peak fluence may be laterally at the peak of the energy cross section. For example, a gaussian beam may have the peak fluence at the waist position, at the maximum of the energy profile. The fluence may control the depth of ablation of the laser light 109 into the material. Lasers with higher fluence may ablate more material.

The laser light 109 may include a selected waist position. The waist position may be the position where the minimum spot size is located. The two-axis scanner 110 may laterally steer the waist position.

The laser light 109 may include a selected beam profile. The beam profile may include a conical cross-section. In embodiments, the laser light 109 may have a Gaussian distribution. In embodiments, the laser light 109 may have a non-Gaussian distribution, such as a flat-top spot, a uniform intensity spot, or the like.

The laser light 109 may include at least one wavelength. The laser light 109 may include any wavelength, such as, but not limited to, 266 nm, 355 nm, 532 nm, 1064 nm, or the like. In embodiments, the laser generator 108 may be a tunable laser generator. For example, the laser generator 108 may tune the laser light 109 between multiple wavelengths. The laser generator 108 may have a tunable wavelength. For example, the laser generator 108 may be tunable over a range, or can be selected from a set of wavelengths (e.g., 1064 nm, 532 nm, 355 nm, 266 nm). The controller 118 may cause the laser generator 108 to change the wavelength of the laser light 109. Changing the wavelength of the laser light 109 may change the Rayleigh length, the spot size, and the like. Changing the wavelength of the laser light 109 may not impact the focus of the detector 116 and/or the properties of the 2D image 117. If an optical element having a large dependence on wavelength is used in conjunction with a laser generator 108 having tunable wavelength, then tuning the wavelength may be used to change the waist position of the laser light 109.

The laser light 109 may include a selected Rayleigh length. The Rayleigh length may be the distance from the waist position where beam radius is minimal to a position where the radius of the laser light 109 is increased by a factor square root of 2.

The repair system 100 may include the two-axis scanner 110. The two-axis scanner 110 may be a two-axis scanner, two-axis fast steering mirror (FSM), a pair of single-axis galvanometer scanners, or the like. The laser light 109 may pass through the two-axis scanner 110. The two-axis scanner 110 may steer the laser light 109 over the area of the defect on the sample 115. The two-axis scanner may scan over a field-of-view. For example, the field-of-view may be a circle with a diameter on the order of 1 to 1000 micrometers, or less. The controller 118 may provide control signals operative to manipulate the two-axis scanner 110 to steer the laser light 109. The two-axis scanner 110 may steer the laser light 109 in two dimensions (X-Y dimensions). The two-axis scanner 110 may have independent control of X-Y positioning. The laser light 109 may be steered to impinge on defects disposed on the sample 115, thereby performing a laser repair operation, such as ablation of spurious conductor deposits.

The repair system 100 may include the beam splitter 106. In embodiments, the laser generator 108 may direct the laser light 109 to the beam splitter 106. The laser light 109 may be directed to the beam splitter 106 via a laser path 111. The laser light 109 from the laser generator 108 may pass through the beam splitter 106. The beam splitter 106 may also combine the optical path of the laser light 109 and the illumination 103 from the light source 102.

The repair system 100 may include the objective lens 112. The objective lens 112 may include one or more optical elements, which may be reflective, refractive, or both. The objective lens 112 may include any suitable lens. In embodiments, the objective lens 112 may include an F-theta lens. The illumination 103 and the laser light 109 may share the objective lens 112. The illumination 103 and the laser light 109 may pass through the objective lens 112. The objective lens 112 may direct the illumination 103 and the laser light 109 onto the sample 115. In particular, the objective lens 112 may direct the laser light 109 to the defects on the sample 115. A (partially) common optical path for the illumination 103 and the laser light 109 may be used to enable accurate calibration and avoid positioning errors. Thus, the laser light 109 may be configured to pass through the objective lens 112 to the sample 115 to perform a repair of a defect located at a defect location 123 on the sample 115.

The repair system 100 may include the z-axis positioner 126. The z-axis positioner 126 may be coupled to the objective lens 112. The z-axis positioner 126 may change the position of the objective lens 112 along the z-axis. The controller 118 may cause the z-axis positioner 126 to change the position of the objective lens 112. The z-axis may be on-axis and/or orthogonal to the sample 115. For example, a height of the objective lens 112 relative to the sample 115 may be defined as a position along the z-axis. Changing the position of the objective lens 112 along the z-axis may shift the focal plane of the detector 116 (i.e., the sample height at which 2D image 117 is focused) and shift the waist position of the laser light 109 relative to sample 115.

The repair system 100 may include an optional medium between the objective lens 112 and the sample 115. The optical medium may include any suitable optical medium, such as, but not limited to, air, an immersion fluid (e.g., water, oil, etc.), and the like.

The repair system 100 may include the sample stage 114. The sample stage 114 may support the sample 115. The repair system 100 may be configured to translate various of the sub-systems relative to the sample stage 114 and the sample 115. For example, the sample stage 114 may be configured to control the X-Y positioning of the sample 115 relative to the illumination 103, the illumination 103a, and/or the laser light 109.

The sample stage 114 may control the Z-positioning of the sample 115 relative to the illumination 103, the illumination 103a, and/or the laser light 109. The repair system 100 may include z-axis positioner 128. The z-axis positioner 128 may be coupled to the sample stage 114. The z-axis positioner 128 may change the position of the sample 115 along the z-axis. The controller 118 may cause the z-axis positioner 128 to change the position of the sample 115. Changing the position of the sample 115 along the z-axis may shift the focal plane of the detector 116 (i.e., the sample height at which 2D image 117 is focused) and shift the waist position of the laser light 109 relative to sample 115.

The sample 115 may include defects. The defects may include excess material defects (e.g., short defects) and/or missing material defects (e.g., open defects). The excess material defect may be an excess of a conductive material, such as copper, or an excess of an insulating material such as substrate, solder resist, or solder mask. The defects may be protrusions, nicks, islands, shorts, opens, and the like. The repair system 100 may be used to repair defects of the sample 115. For example, the laser light 109 may ablate the excess material defect to repair the sample 115. The laser light 109 may repair the excess material defect by ablating the excess solid material.

In embodiments, the repair system 100 may include collected light 119. The illumination 103 and/or the illumination 103a may reflect or be emitted from the defect location 123 of the sample 115 as the collected light 119. The laser light 109 may also reflect or be emitted from the defect location 123 of the sample 115 as the collected light 119. The collected light 119 reflecting or being emitted from the defect location 123 of the sample 115 may also include fluorescence emitted from the defect location 123 of the sample 115 following excitation by the illumination 103, illumination 103a, and/or laser light 109. The illumination 103, the illumination 103a, and/or the laser light 109 may cause a portion of the defect location 123 of the sample 115 to fluoresce. Thus, the collected light 119 may include a specular reflection of on-axis illumination, diffuse reflection of off-axis illumination, reflected laser light, and/or fluorescence emitted by the defect location 123 of the sample 115 upon excitation. The collected light 119 may be different than the illumination 103, the illumination 103a, and/or the laser light 109 in spectrum, optical power, and/or direction.

The collected light 119 may reflect or be emitted from the defect location 123 of the sample 115 along a collection path 113. The collected light 119 may reflect or be emitted from the sample 115 through the objective lens 112, the beam splitter 106, and/or the beam splitter 104. The collected light 119 may reflect or be emitted from the defect location 123 of the sample 115 to the detector 116.

The repair system 100 may include the detector 116. The detector 116 may be configured to capture the collected light 119. In this regard, the detector 116 may receive the collected light 119 reflected, emitted, or scattered (e.g., via specular reflection, diffuse reflection, and the like) from the defect location 123 of the sample 115. The detector 116 may be a camera. The detector 116 may include any type of optical detector suitable for measuring light received from the sample 115. For example, the detector 116 may include, but is not limited to, a CCD detector, a TDI detector, a photomultiplier tube (PMT), an avalanche photodiode (APD), a complementary metal-oxide-semiconductor (CMOS) sensor, or the like.

The detector 116 may be configured to generate a 2D image 117 of the defect location 123 based on the collected light 119. The 2D image 117 may include a reflectance image of the defect location 123 of the sample 115 or an image of fluorescence emitted by the defect location 123 of the sample 115. The reflectance image may be, for example, an image of the defect being scanned by the laser light 109. Different reflectance images may be acquired under different configurations of the illumination 103, the illumination 103a, and/or the laser light 109. The fluorescence image may provide a higher contrast between a substrate which may fluoresce and conductors which may not fluoresce. For example, the fluorescence image may indicate an edge between copper and substrate. Fluorescence images may be illuminated with violet or ultraviolet light, and filter the violet/UV light to capture the fluorescence light from the sample 115 and not the violet/UV light. The controller 118 may be configured to detect the edges between the between copper and substrate. The controller 118 may detect a 2D shape of a defect using the edge between the copper and substrate.

The repair system 100 may include filters 134. The filters 134 may be disposed in the collection path 113. For example, the filters 134 may be disposed in the collection path 113 between the detector 116 and the beam splitter 104. The filters 134 may include, but are not limited to, high pass filters, low pass filters, band-pass filters and/or notch filters. The filters 134 may be configured to filter the collected light 119. For example, the filters 134 may be configured to filter the violet/UV light from the collected light 119, allowing the detector 116 to capture the fluorescence light from the sample 115 and not the violet/UV light.

The repair system 100 may include z-axis positioner 130. The z-axis positioner 130 may be coupled to the detector 116. The z-axis positioner 130 may change the position of the detector 116 along the z-axis. The controller 118 may cause the z-axis positioner 130 to change the position of the detector 116. Changing the position of the detector 116 along the z-axis may shift the focal plane of the detector 116 (i.e., the focus of the 2D image 117) but may not shift the waist position of the laser light 109. The z-axis positioner 130 may be used in combination with the z-axis positioner 126 and/or the z-axis positioner 128 to maintain the focus of the detector 116 while shifting the waist position of the laser light 109. The z-axis positioner 130 may be used in combination with the z-axis positioner 126 and/or the z-axis positioner 128 to alter the focus of the detector 116 while maintaining the waist position of the laser light 109 on the sample 115.

The repair system 100 may be configured to generate a 3D measurement 121. The 3D measurement 121 may be a three-dimensional measurement associated with the sample 115. The 3D measurement 121 may differentiate between heights, also referred to as depths, of the sample 115. For example, the 3D measurement 121 may include a height profile of a defect region on the sample 115. The height profile of the sample 115 may include heights of conductors, excess material defects, and/or a substrate of the sample 115. The 3D measurement 121 may or may not differentiate between materials of the sample 115. For example, the 3D measurement 121 may not differentiate between the conductors, excess material defects, and substrate of the sample 115.

The 3D measurement 121 may be generated in the collection path 113 and/or may be generated outside the collection path 113. The 3D measurement 121 may or may not be generated based on the collected light 119. For example, the 3D measurement 121 may be generated in the collection path 113 based on the collected light 119. The repair system 100 may be configured to generate the 3D measurement 121 using depth from focus, interferometry, chromatic confocal microscopy, or the like. As depicted, the 3D measurement 121 is generated by a 3D camera 132 and received by the controller 118, although this is not intended to be limiting. It is further contemplated that the 3D measurement 121 may be generated by the controller 118 from the 2D images 117 using depth from focus.

In embodiments, the repair system 100 may be configured to generate the 3D measurement 121 using depth from focus. The repair system 100 may generate a stack of the 2D image 117 where there is an inter-image shift in a focal plane between every pair of consecutive of the 2D images 117. The inter-image shifts in the focal plane between the 2D images 117 may or may not be equal across all of the 2D images 117. The inter-image shifts in the focal plane may decrease towards the substrate of the sample 115. For example, the inter-image shifts in the focal plane between pairs of the 2D images 117 which are focused further from the substrate may be larger and the inter-image shifts in the focal plane between pairs of the 2D images 117 which are focused closer to the substrate may be smaller. Thus, a higher resolution may be provided near the substrate. The repair system 100 may control the shift of the focal plane of the 2D image 117 by moving the objective lens 112 using the z-axis positioner 126, by moving the sample 115 using the z-axis positioner 128, and/or by moving the detector 116 using the z-axis positioner 130. A pixel in the 2D image 117 which is in focus at the depth of focal plane may indicate the pixel in the sample 115 (e.g., conductor, excess material defect, or substrate of the sample 115) is at the depth of the focal plane. The 3D measurement 121 may be generated from a stack of the 2D image 117 with a shift in focal planes using the depth from focus. The depth estimation of a pixel need not coincide with any of the focal planes of stack of the 2D images 117, and may be at a depth in-between the various of the 2D images 117.

In embodiments, the repair system 100 may be configured to generate the 3D measurement 121 using a 3D camera 132. The repair system 100 may include the 3D camera 132. The controller 118 may cause the 3D camera 132 to generate the 3D measurement 121. The 3D camera 132 may include an interferometer, a confocal microscope (e.g., a chromatic confocal microscope), or the like. For example, the interferometer may include a white light interferometer (WLI), phase shifting interferometer (PSI), vertical scanning interferometer (VSI), coherence scanning interferometer (CSI), shearing interferometer, or the like. The 3D camera 132 may or may not share the illumination path 105, the laser path 111, the objective lens 112, the detector 116, and/or the collection path 113. The specific configuration of the 3D camera 132 sharing the illumination path 105, the laser path 111, and/or the collection path 113 is not depicted in the interest of clarity.

The 3D measurement 121 may have a 3D accuracy limit. The 3D accuracy limit may be a minimum depth at which the 3D measurement 121 is able to contrast. The 3D accuracy limit may be based on a wavelength of light used to generate the 3D measurement 121. For example, the 3D accuracy limit may be a sub-wavelength of the light used to generate the 3D measurement. For instance, the 3D accuracy limit may be a sub-wavelength of the illumination 103, where the 3D measurement 121 is generated from the 2D images 117 (e.g., from the collected light 119). The 3D measurement 121 may detect depths above the 3D accuracy limit but may be unable to detect depths below the 3D accuracy limit. For example, the 3D measurement 121 may include a 3D accuracy limit of one-hundred nanometers. The 3D measurement 121 may be able to detect excess material defects thicker than one-hundred nanometers on a substrate of the sample 115 but may not preclude the existence of a fine short between conductors that is less than or equal to one-hundred nanometers in thickness. The use of the 3D measurement 121 during repair using the laser light 109 may result in the fine short remaining between conductors. However, the fine short may be further repaired using the 2D images 117 as will be described further herein.

The repair system 100 may include the controller 118. The controller 118 may include one or more processors 122 configured to execute program instructions maintained in memory 124. In this regard, the one or more processors 122 of controller 118 may execute any of the various process steps described throughout the present disclosure.

In embodiments, the memory 124 may include a design file. The design file may represent the design to which the sample 115 should adhere. The design file may include a design resolution of a line. The design resolution may include two-dimensional (2D) data about the line. For instance, the design resolution may include a line width. The design resolution may also include three-dimensional (3D) data about the line. For instance, the design resolution may include a line thickness, also referred to as depth. The design file may also include a thickness of the substrate. The design file may be derived from computer aided manufacturing (CAM). The design file may be a CAM file or CAM data. The design file may include a map of contours, namely edges between conductor and substrate, corresponding to the electrical circuit to be inspected. The design file may include information about the conductor cross section, such as an angle and/or ratio between pattern line and space.

The controller 118 may process the design file to understand what is in the design. The controller 118 may understand what portions of the design are lines, pads, vias, and the like. For example, the controller 118 may measure the nearest neighbor conductors for every point in the design file. Coarser designs may have a further distance to the nearest neighbor conductors. Finer designs may have smaller distances to the nearest neighbor conductors.

In embodiments, the memory 124 may include a defect report. The controller 118 may receive the defect report from an automated optical inspection (AOI) system, or the like, and store the defect report in the memory 124. The AOI system may be an upstream tool that may inspect the sample 115 and may determine where the defect candidates are located. The defect report may also be referred to as an AOI report or the like. The defect report may include the defect location 123 of one or more defects on the sample 115. The defect report may include repair-assisting information such as type of defect, quantity of laser pulses to be delivered, laser fluence, and the like. Although the defect report is described as including the quantity of laser pulses to be delivered and the laser fluence, this is not intended as a limitation of the present disclosure. The quantity of laser pulses to be delivered, the laser fluence, and the like may be part of a repair recipe.

The controller 118 may be communicatively coupled to the detector 116. The controller 118 may be configured to receive data including, but not limited to, 2D image 117 from the detector 116, the 3D measurement 121, and the like. The controller 118 may cause the detector 116 to generate the 2D image 117 of the defect location 123 of one or more defects on the sample 115. For example, the controller 118 may cause the detector 116 to generate the 2D image 117 of the defect location 123 at defect locations from the defect report. The controller 118 may also generate the 3D measurement 121. The controller 118 may cause the repair system 100 to generate the 3D measurement of the defect location 123 at the defect locations. The controller 118 may cause the repair system 100 to generate the 3D measurement 121 from the 2D image 117 by generating a stack of the 2D image 117 with a shift in the focal plane and determining depth from focus and/or using the 3D camera 132.

The repair system 100 may load the panel design and the defect report with the coordinates of the defects into the memory 124. The sample 115 may be loaded onto the sample stage 114. The repair system 100 may go to the defect location 123 on the sample 115 based on the defect report. For example, the repair system 100 may go to the defect location 123 on the sample 115 using an X-Y positioner to position the objective lens 112 above the defect location 123. The repair system may perform a closed-loop short repair using combined 2D image 117 and 3D measurement 121 at the defect location 123. For example, the repair system 100 may generate the 3D measurement 121, ablate the 3D shape of the excess material determined from the 3D measurement 121 up to the 3D accuracy limit, generate the 2D image 117 to determine residues below the 3D accuracy limit, and ablate the residues. The repair system may then go to the next defect for the defect in the defect report.

In embodiments, the repair system 100 may include the user interface 120. The user interface 120 may be communicatively coupled to the controller 118. In embodiments, the user interface 120 may include, but is not limited to, one or more desktops, laptops, tablets, and the like. In embodiments, the user interface 120 may include a display used to display data of the repair system 100 to a user. The display of the user interface 120 may include any display known in the art. For example, the display may include, but is not limited to, a liquid crystal display (LCD), an organic light-emitting diode (OLED) based display, or a CRT display. Those skilled in the art should recognize that any display device capable of integration with a user interface 120 is suitable for implementation in the present disclosure. In another embodiment, a user may input selections and/or instructions responsive to data displayed to the user via a user input device of the user interface 120.

The illumination path 105, laser path 111, and/or the collection path 113 may include additional optical components. The additional optical components may be suitable for modifying and/or conditioning the illumination 103, illumination 103a, laser light 109, and/or the collected light 119. For example, the one or more optical components may include, but are not limited to, objective lens assembly 136, zoom actuator 138, iris 140, variable beam expanders 142, diffractive optical elements 144, lenses, polarizers, filters, beam splitters, diffusers, homogenizers, apodizers, shapers, shutters (e.g., mechanical shutters, electro-optical shutters, acousto-optical shutters, or the like), aperture stops, field stops, and the like. The repair system 100 may include any combination of the optical components. For instance, the controller 118 may control any of the objective lens assembly 136, the zoom actuator 138, the iris 140, the variable beam expander 142, and/or the diffractive optical element 144 to change the optical properties of the illumination 103, laser light 109, and/or collected light 119 based on either open loop conditions, for example a predefined repair flowchart, or based on closed loop conditions, for example feedback from the 2D image 117 and/or 3D measurements during the repair of the defects.

The objective lens assembly 136 may include multiple of the objective lens 112. The objective lens 112 may include a magnification, numerical aperture, and the like. The objective lens assembly 136 may change between the objective lens 112. The controller 118 may cause the objective lens assembly 136 to change between the objective lens 112 through which the illumination 103 and/or the laser light 109 and/or the collected light 119 is configured to pass. Changing the objective lens 112 may refer to placing the objective lens 112 in the path of the illumination 103 and/or the laser light 109 and/or the collected light 119. For example, the objective lens assembly 136 may rotate between the objective lens 112 where the objective lens assembly 136 is an objective lens turret. By way of another example, the objective lens assembly 136 may linearly translate between the objective lens 112 where the objective lens assembly 136 includes a linear stage of the objective lens assembly 136. Changing between the objective lens 112 may change the field-of-view, the image magnification, the numerical aperture, the image pixel size, the image depth-of-field, the Rayleigh length of the laser beam, the spot size, and the like. The repair system 100 may then change between the objective lens 112 to process conductors which have significantly different spacing between adjacent conductors.

In embodiments, the repair system 100 may use multiple of the objective lens 112. The repair system 100 may include a first objective lens for the illumination 103 and a second objective lens for the laser light 109. The first objective lens may be used for 3D measurement or for 2D image 117 with a high resolution. For example, the first objective lens may be used when taking a 3D measurement of the defect, or when acquiring 2D image 117 for accurate defect identification. The first objective lens may include a magnification which is higher than the magnification of the second objective lens. The higher magnification may be undesirable for the repair, because the higher magnification reduces the spot size of the laser below a minimum size. Reducing the spot size of the laser below the minimum size may significantly reduce the speed of the repair and increase the fluence (e.g., depth of penetration). In this regard, a resolution of the collected light 119 may change without changing the spot size of the laser light 109.

The zoom actuator 138 may be coupled to the objective lens 112. The zoom actuator 138 may control a magnification of the objective lens 112. The controller 118 may cause the zoom actuator to control the magnification of the objective lens 112. For example, the objective lens 112 may be a zoom objective lens. Changing the magnification of the objective lens 112 may change the field of view, the image magnification, the numerical aperture, the Rayleigh length, the spot size, and the like. The zoom actuator 138 may include a zoom motor, an electric field generator, or the like. For example, the objective lens 112 may change magnification when an electric field is applied by the zoom actuator 138.

The iris 140 may be disposed in the pupil plane of the objective lens 112, or a conjugate plane thereof. The iris 140 may control the numerical aperture of the objective lens 112. The iris 140 may be external or internal to the objective lens 112. Where the iris 140 is internal to the objective lens 112, the objective lens 112 may be a variable aperture objective lens. The controller 118 may cause the iris 140 to change the aperture of the objective lens 112. For example, the controller 118 may change the aperture of the iris 140 using an actuator or the like. Changing the aperture of the objective lens 112 changes the image intensity, the numerical aperture, the Rayleigh length, the spot size, and the like.

The variable beam expander 142 may change the diameter of the laser light 109, and subsequently the laser spot size, the Rayleigh length, and the like. The controller 118 may cause the variable beam expander 142 to change the diameter of the laser light 109. The variable beam expander 142 may not impact the focus of the detector 116 and/or the properties of the 2D image 117.

The diffractive optical element 144 may be in the laser path 111. For example, the diffractive optical element 144 may be in the laser path 111 between the laser generator 108 and the two-axis scanner 110. The controller 118 may control the diffractive optical element 144. For example, the diffractive optical element 144 may be inserted or removed from the laser path 111. The diffractive optical element 144 may include a tunable phase element or the like. The diffractive optical element 144 may change the beam profile of the laser light 109. The controller 118 may cause the diffractive optical element 144 to change the beam profile of the laser light 109. Changing the beam profile may improve ablation depth uniformity (e.g., using a top-hat profile) or avoiding damage to the pattern conductors (e.g., using a Gaussian profile). The Gaussian distribution may be desirable for most applications. The diffractive optical element 144 may change the beam profile of the laser light 109 to a non-Gaussian distribution. For example, the diffractive optical element 144 may change the beam profile to a flat top spot or a uniform intensity spot. The diffractive optical element 144 may not impact the focus of the detector 116 and/or the properties of the 2D image 117.

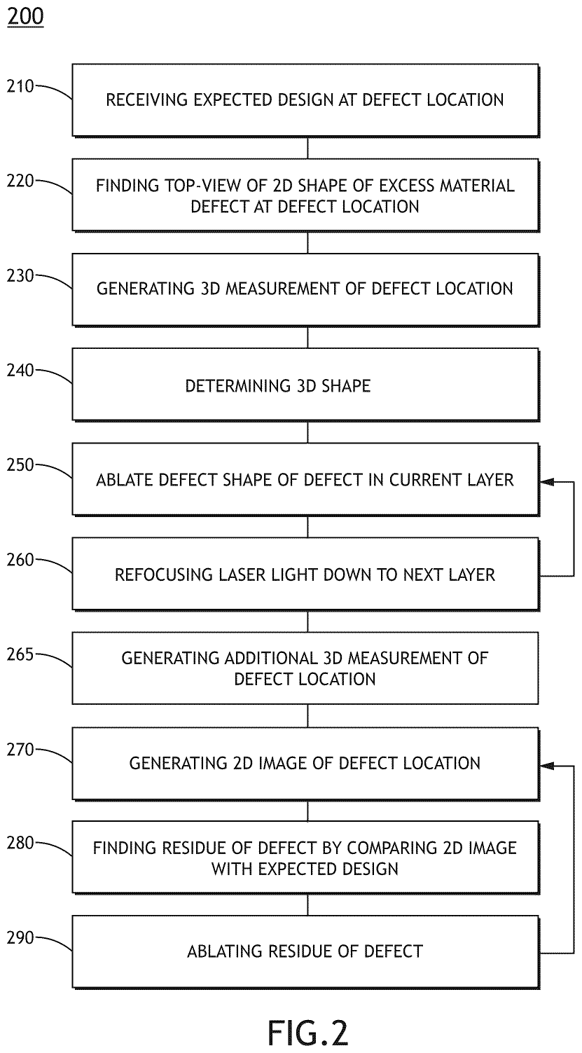

Referring now to FIG. 2, a method 200 is described, in accordance with one or more embodiments of the present disclosure. The method 200 may be a method of closed-loop short repair using combined 2D and 3D. The embodiments and the enabling technologies described previously herein in the context of the repair system 100 should be interpreted to extend to the method. It is further noted, however, that the method is not limited to the architecture of the repair system 100.

In a step 210, an expected design at the defect location may be received. The expected design may include a two-dimensional and/or a three-dimensional design at the defect location 123. For example, the expected design may include the three-dimensional design with the two-dimensional design plus a depth. The controller 118 may receive a design file of the sample 115. The design file may be the expected design (e.g., a panel design). The controller 118 may also receive a defect report of the sample. The controller 118 may receive the defect report of the sample 115 from an AOI system, or the like. The defect report may include the defect location 123 of defects on the sample 115. The expected design may be a 3D measurement of the design, a model of the design, or the like.

In a step 220, a top-view of 2D shape of an excess material defect at the defect location may be found by comparing a 2D image to a design. For example, the 2D image 117 may be compared with the design file of the sample 115 at the defect location 123 to determine the top-view of 2D shape of an excess material defect. The repair system 100 may generate the 2D image 117. The detector 116 may generate the 2D image 117 at the defect location 123. The 2D image 117 may include a panel image, or the like. The controller 118 may identify the defect by comparing the actual pattern at the defect location 123 in the 2D image 117 to the expected pattern at the defect location 123 in the design file. For example, the controller 118 may identify dimensions (e.g., a size (X-Y)) of the defect from the top-view of the 2D shape of the excess material defect. Finding the top-view of 2D shape of the excess material defect may be an optional step. For example, the 2D image 117 may or may not be captured. Although the method 200 is described as finding the top-view of the 2D shape, this is not intended as a limitation of the present disclosure. Finding the top-view of the 2D shape may be an optional step.

In a step 230, a 3D measurement of a defect location may be generated. For example, the 3D measurement 121 of the defect location 123 may be generated using the repair system 100. The 3D measurement may include the defect and/or one or more conductors which may be adjacent to the defect at the defect location 123. The controller 118 may generate the 3D measurement 121 from multiple of the 2D images 117 and/or cause the 3D camera 132 to generate the 3D measurement 121.

In a step 240, a 3D shape of the excess material defect may be determined by comparing the 3D measurement to the design. The 3D shape may be found by subtracting the design from the 3D measurement. The remainder after the subtraction may be the 3D shape of the excess material up to the 3D accuracy limit. For example, the controller 118 may determine the 3D shape of the excess material defect by comparing the 3D measurement 121 to the design of the sample 115 at the defect location 123. The 3D shape of the defect may be a thickness at every XY pixel.

The 3D shape of the excess material defect may be sliced into multiple defect shapes. The defect shapes may be stacks of layers of the 3D shape of the excess material defect to be removed. The defect shapes may be removed in one or more ablation cycles. The 3D shape may be sliced into any integer number of the defect shapes. The number of the defect shapes may be based on the depth of the 3D shape of the defect and the ablation depth of the laser light 109. A single of the 3D measurement 121 may yield the defect shapes for the ablation cycles up to the 3D accuracy limit.

In a step 250, the defect shape of the defect in a current layer may be ablated by scanning the laser light at the defect shape. For example, the excess material defect may be ablated by scanning the laser light 109 at the defect shape. The laser light 109 may ablate the excess material defect at the defect location 123 to remove a layer of the excess material defect.

The repair system 100 may focus the laser light 109 at the excess material at the top of the excess material defect. The repair system 100 may determine the top of excess material defect from the 3D shape. For example, the top of the defect may be determined from the highest focal plane at which the defect is in focus.

Similarly, the repair system 100 may determine the defect shapes of the excess material defect from the 3D shape. For example, the 3D shape may be segmented into defect shapes which are stacked together. A topmost of the defect shapes may be ablated by scanning the laser light 109 in a pattern of the defect shape. For instance, the laser light 109 may be scanned at the defect location 123 along the topmost of the defect shapes in the stacks of layers to remove a topmost layer of the defect. The layer may correspond to a topmost shape of the 3D shape of the excess material defect. The repair system 100 may control the waist position of the laser light 109 as the laser light 109 by the two-axis scanner 110 steering the laser light 109 to scan the laser light 109 along the layer. For example, the waist position of the laser light 109 may be controlled in the X-Y plane. Scanning the laser light 109 in the pattern of the defect shape may prevent scanning the laser light 109 at the portion of the defect below the current layer. The defects may not include a uniform depth. Scanning the laser light 109 at the portion of the defect below the current layer may cause the laser light 109 to be defocused at that position. When the laser waist is in air, the laser light 109 may defocus and may illuminate a larger area on the defect and/or cause the laser light 109 to hit the reference conductor or the substrate. Thus, the repair system 100 may achieve a speed advantage as well as a quality advantage by following the scanning the laser light 109 in the pattern of the defect shape and not scanning the laser light 109 on the air above the next layers of the defect.

The repair system 100 may achieve a further speed advantage by combining the XY scanning of the defect shape with real-time Z adjustment such that the removed layer is not planar but follows the top surface of the defect. The repair system 100 may control the waist position of the laser light 109 as the laser light 109 is scanned along the defect. For example, the controller 118 may direct the waist position causing the laser light 109 to follow the height profile of the defect. The repair system 100 may focus the waist position of the laser light 109 to follow along the height profile. Each of the pulses of the laser light 109 may follow along the height profile. Focusing the waist position of the laser light 109 along the height profile may reduce the number of pulses required for repair, resulting in a shorter repair time. Controlling the waist position as the laser light 109 is scanned to follow the 3D profile may be desirable to reduce the number of scans performed by the repair system 100, and similarly reduce the repair time.

The layer may include a selected depth of the excess material. The excess material may be ablated using the laser light 109 with one or more optical properties. The optical properties may determine the selected depth of the current ablation layer. The optical properties may be set according to an ablation recipe or the like.

The pattern of the pulses of the laser light 109 can be performed sequentially or non-sequentially in space. For example, the pattern of the pulses may be scanned sequentially. By way of another example, the pattern of the pulses may be directed non-sequentially by using acousto-optic deflectors which direct the pulses to different coordinates in a non-serial fashion. As used herein, scanning may refer to directing the pulses either sequentially or non-sequentially. However, the pattern of the pulses of the laser light 109 may be the defect shape.

In a step 260, the laser light may be refocused down to a next layer. For example, the laser light 109 may be refocused down to a next layer. The repair system 100 may refocus the laser light 109 down to a next layer for ablating the next layer of the excess material. The repair system 100 may then ablate the defect by removing one or more layers of the excess material at the next layer.

The controller 118 may be configured to ablate the defect shape of the defect in the current layer by scanning the laser light 109 at the defect shape one or more times before refocusing the laser light 109 down to the next layer. For example, the controller 118 may ablate the defect shape of the defect in the current layer by scanning the laser light 109 at the defect shape one time before refocusing the laser light 109 down to the next layer. By way of another example, the controller 118 may ablate the defect shape of the defect in the current layer by scanning the laser light 109 at the defect shape multiple times before refocusing the laser light 109 down to the next layer. The laser light 109 may include a larger fluence where the laser light 109 is scanned at the defect shape one time before refocusing the laser light 109 down to the next layer and a smaller fluence where the laser light 109 is scanned at the defect shape multiple times before refocusing the laser light 109 down to the next layer. The reduction in fluence of the laser light 109 may be beneficial to reduce a debris caused by ablation of the defect.

Although the controller 118 is described as refocusing the laser light 109 down to the next layer, this is not intended as a limitation of the present disclosure. The controller may ablate the defect shape multiple times and complete repair without refocusing in any of the layers, by changing other properties instead. For example, the controller 118 may perform multiple ablations while varying the fluence or the spot size without refocusing. Thus, the focus plane of the laser light 109 may be fixed when ablating multiple of the layers.

The repair system 100 may ablate the 3D shape of the defect by iteratively ablating the defect and refocus the laser light 109 down to the next layer. The repair system 100 may iteratively repeat directing the pulses of the laser light 109 and refocusing to ablate the 3D shape determined from the 3D measurement 121. The repair system 100 may focus the laser light 109 to perform multiple layers of scans of the laser light 109 from the top of the excess material defect to ablate the 3D shape.

The controller 118 may determine that the 3D shape of the excess material has been ablated using one or more open loop and/or closed loop conditions. For example, the controller 118 may estimate the depth ablated at the current layer using the fluence of the laser light 109 as an open loop condition. The open loop condition may be a depth ablated at the current layer estimated by the controller 118 using a fluence of the laser light 109. A defect thickness (T) is to be removed. The ablation area can be automatically adjusted every iteration according to the thickness expected to be removed by that iteration. The defect thickness (T) may be known from the 3D measurement 121. The pulses of the laser light 109 may remove a thickness (t) of the excess material defect. The thickness (t) may be a function of fluence and spot size (which is itself a function of waist size and defocus, if any). The number of ablation cycles may be based on the defect thickness (T) and the thickness (t) removed in the current ablation layer. A defect thickness (T) is expected to be ablated within (n) iterations where each of the iterations remove a thickness (t), such that n=T/t. The thickness (t) may be different for every coordinate within the defect area as it may not be planar, hence the laser spot size may be defocused at some coordinates. Since the defect profile is known from the 3D measurement 121, the controller 118 may adjust (t) per-coordinate, and estimate (n) per-coordinate even for non-planar defects with varying thickness and varying defocus. Ablating and refocusing removes the 3D shape determined by comparing the 3D measurement 121 which is determined initially before ablation with the expected design. Thus, the repair system 100 may ablate the excess material defect and refocus down to the next working depth without generating additional of the 3D measurement 121. For example, additional of the 3D measurements may not be generated while iteratively ablating the defect shape in the current layer and refocusing the laser light 109 down to the next layer.

In embodiments, the repair system 100 may perform several scans at a given focus before refocusing. For example, the repair system 100 may use the laser light 109 to perform repeated ablations when the aggregate removed depth at the focus position is less than the order of the Rayleigh length of laser light 109. Performing the repeated scans between focus adjustments may be desirable to reduce the number of refocusing actions, thereby saving time and/or improving accuracy. The repair system 100 may refocus the laser light 109 when the aggregate removed depth from last focus position is on the order of the Rayleigh length of laser light 109. For example, if the Rayleigh length is 2 μm and the ablations remove 0.5 um of material, then repair system 100 may refocus the laser light 109 every 4 ablations. Thus, the laser light 109 may be refocused as needed.

The 3D shape of the defect removed by ablating and refocusing may not include the entire portion of the defect. A residue of the defect may remain after the ablating and refocusing to ablate the 3D shape from the defect. The residue of the defect may be below the 3D accuracy limit of the 3D measurement 121. The residue of the defect may be invisible to the 3D measurement 121. Performing additional of the 3D measurement 121 may be unable to determine the residue of the defect. An additional of the 3D measurement 121 after the ablation cycles may not improve the 3D accuracy limit of the 3D measurement 121. Iteratively ablating and refocusing to ablate the 3D shape may ablate the defect up to the 3D accuracy limit. For example, the residue of the defect may be a fine short. Thus, repair using the 3D measurement 121 may result in the fine short.

In a step 265, an additional 3D measurement of the defect location may be generated. For example, an additional of the 3D measurements 121 of the defect location 123 may be generated using the repair system 100. The additional of the 3D measurements 121 may indicate that there is a defect remaining at the defect location or that there is no defect remaining at the defect location. Where the 3D measurement 121 indicates there is defect remaining at the defect location, the method may return to the step of determining the defect 3D shape. Generating the additional of the 3D measurements 121 of the defect location 123 may be an optional step.

In a step 270, a 2D image of the defect location may be generated. For example, the 2D image 117 of the defect location 123 may be generated. For instance, the controller 118 may cause the detector 116 to generate the 2D image 117. The 2D image 117 may be a top view of the defect at the defect location 123. The 2D image 117 may include the residue of the defect which is below the 3D accuracy limit of the 3D measurement. The 2D image 117 may be acquired after one or more of the layers of laser scans.

In a step 280, the residue of defect may be found by comparing the 2D image with the expected design at the defect location 123. For example, the residue of the defect may be found by finding in the 2D image 117 the edges between the residue of the defect and the substrate. The edges may be compared with the edges in the expected design at the defect location 123. The residue of the defect may then be found by comparing the edges in the 2D image 117 and the edges in the expected design.

Where the additional of the 3D measurements 121 of the defect location 123 indicates there is no residue at the defect location and the residue of the defect is found by comparing the 2D image due to the height of the defect being below the 3D accuracy limit of the 3D measurement 121, a height of the residue of the defect may be determined to be below the 3D accuracy limit of the 3D measurements 121. The fluence of the laser light 109 may then be adjusted to ablate a thickness below the 3D accuracy limit of the 3D measurements 121.

In a step 290, the residue of the defect may be ablated by scanning laser light at the defect location based on the 2D image. For example, the residue of the defect may be ablated by scanning the laser light 109 at the defect location 123 based on the 2D image 117. The regions close to the substrate which are below the 3D accuracy limit may be ablated.

A portion of the residue of the defect may or may not remain after ablating the residue of the defect. The repair system 100 may iteratively generate the 2D image 117 of the defect location 123, find the residue of the defect, and ablate the residue of the defect. The repair system 100 may perform multiple scans of the laser light 109 directed at the residue of the defect. The repair system 100 may focus the laser light 109 at the residue of the defect. Additional of the 2D image 117 may be acquired after each scan. The repair system 100 may iteratively acquire the 2D image of the defect location, find the residue of the defect, and ablate the residue of the defect until at least one of a criteria is met. The criteria may include determining the defect has been repaired. For example, the controller 118 may determine that the defect has been repaired by detecting that the defect is no longer present at the defect location 123 in the 2D image 117 (e.g., from a fluorescence image). By way of another example, the controller 118 may determine that the residue of the defect is below an allowable defect size. Thus, the repair system 100 may use the 2D image 117 to cause the laser light 109 to remove the defect up to the substrate of the sample 115, as determined from the 2D image 117.

The repair system 100 may or may not refocus the laser light 109 at a different depth when iteratively generating the 2D image 117 of the defect location 123, finding the residue of the defect, and ablating the residue of the defect. For example, the repair system 100 may be unable to determine a depth of the residue of the defect below the 3D accuracy limit such that refocusing may not be performed. It is further contemplated that the repair system 100 may refocus the laser light 109 based on open-loop feedback. The open-loop feedback may include refocusing the laser light 109 based on the 3D accuracy limit from the top of the substrate and an ablation depth of the laser light 109. For example, the laser light 109 may be focused at the 3D accuracy limit above the top of the substrate and then refocused at a next layer based on the ablation depth.

In embodiments, the repair system 100 may iteratively perform one or more steps of the method to repair the defect for the known defects (e.g., the defects in a defect report). For example, the repair system 100 may load a panel design (e.g., CAM) and coordinates for the defects from a defect report. The sample 115 may be loaded onto the sample stage 114. The repair system 100 may go to the defect coordinates for the defects in the defect report and perform the steps of the method to repair the defect for the known defects.

The repair system 100 may use the 2D image 117 and the 3D measurement 121 to combine both accuracy and speed. Using the 3D measurement 121 to perform the scans of the laser light 109 up to the 3D accuracy limit followed by using the 2D image 117 to perform the scans of the laser light 109 may provide a speed and/or accuracy improvement when repairing the defect at the defect location 123. The repair system 100 may use a higher speed when repairing defect regions further from the substrate. Starting from a 3D measurement may save imaging and processing times for multiple cycles. For example, generating the 3D measurement 121 may be slower than generating the 2D image 117 on a per measurement basis. However, there may be one of the 3D measurements 121 during the repair as compared to using multiple of the 2D images 117 to perform the repair up to the 3D accuracy limit of the 3D measurement. An aggregate time to generate the 2D images 117 (image acquisition and calculation) may be longer than the aggregate time to generate the 3D measurement 121. Calculating the edge between the excess material and the substrate in the 2D images 117 may be computationally intensive as compared to determining the defect depth, for example using a focus-based method. The repair system 100 may also achieve high accuracy at defect regions close to the substrate. The 2D image 117 may provide high contrast to accurately identify defects close to the substrate of the sample 115. Limited 3D accuracy may be addressed by acquiring a fluorescence image at least at the end of repair, to detect any fine shorts and remove all unacceptable residues. By using information from the 3D measurement 121 and the 2D image 117, the repair may benefit both from time savings from to the 3D measurement 121 and the accuracy from the 2D image 117. The throughput of the repair system 100 may be increased as compared to repairing the excess material defect using only the 2D image 117. The accuracy of the repair system 100 may be Increased as compared to repairing the excess material defect using only the 3D measurement. Remaining defects which are below the sensitivity of the 3D measurement system may be ablated using the 2D images 117.

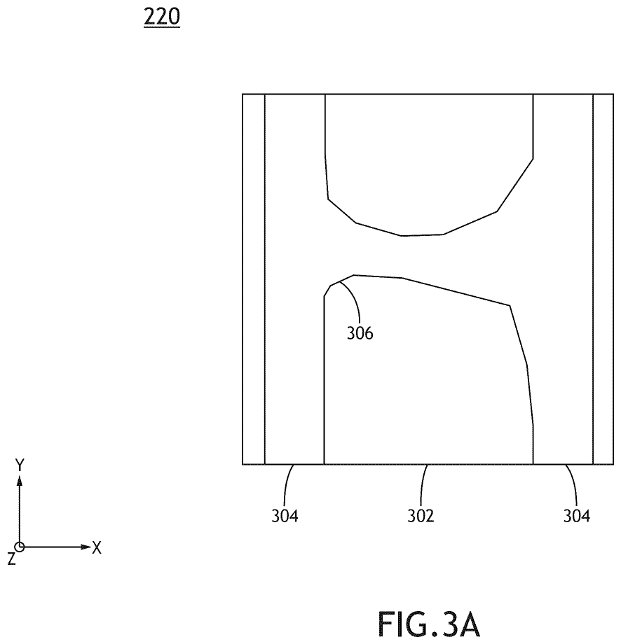

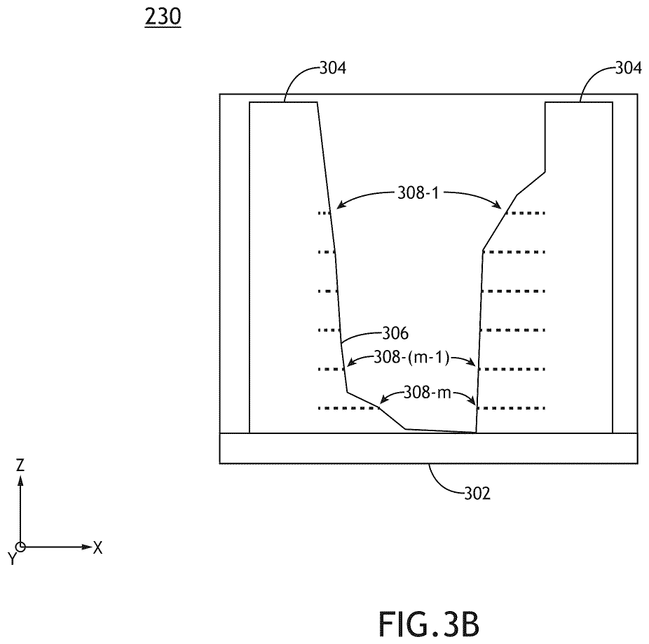

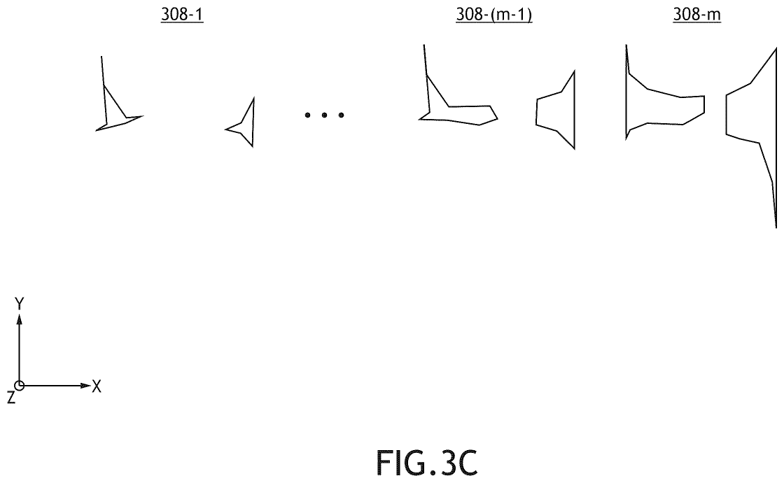

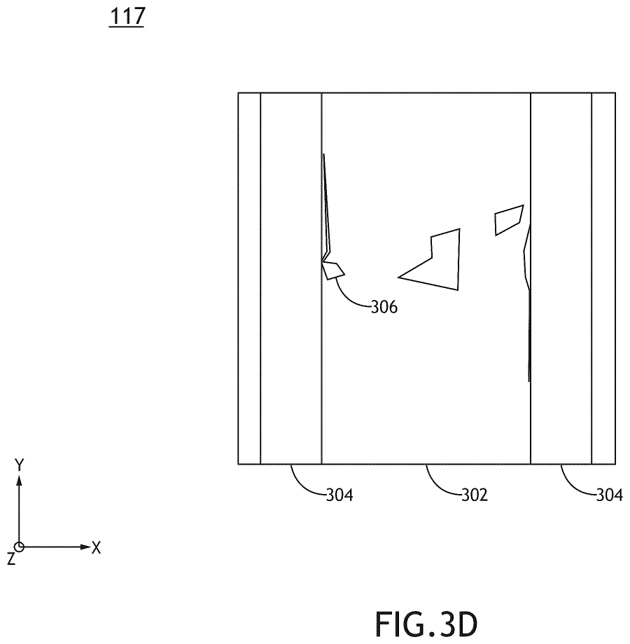

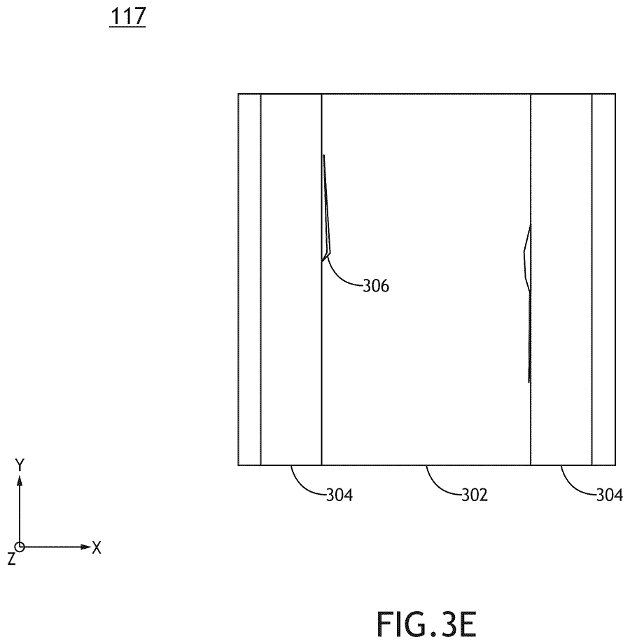

Referring now to FIGS. 3A-3E, an example of repair of a defect at the defect location 123 of the sample is described using the combined 2D and 3D repair, in accordance with one or more embodiments of the present disclosure. The defect location 123 may include a substrate 302, conductors 304, and excess material defect 306, and the like. The conductors 304 and excess material defect 306 may be disposed on substrate 302 of the sample 115. The conductors 304 may include a selected line width and a selected space width. The line width may refer to a width of the conductors 304. The space width may refer to a width of space between the conductors 304. The excess material defect 306 may be disposed between the conductors 304. The excess material defect 306 may be a short between the conductors 304. The conductors 304 and the excess material defect 306 may be formed of a conductive material, such as copper, or the like.

The repair system 100 may generate the 3D measurement 121. The 3D measurement 121 may include the substrate 302, conductors 304, and excess material defect 306. The 3D shape of the excess material defect may be determined by comparing the 3D measurement 121 to the expected design. The repair system 100 may determine defect shapes 308 to remove from the excess material defect 306. The defect shapes 308 may include defect polygons or the like. For example, the repair system 100 may determine defect shape 308-1 through defect shape 308-m, where m is an integer. In the example depicted, six of the defect shapes 308 are determined from the 3D measurement 121, although this is not intended to be limiting. The sum of the defect shape 308-1 through defect shape 308-m may be the 3D shape determined from the 3D measurement 121.

The defect shapes 308 may indicate the shape of the excess material defect 306 to be removed when scanning the excess material defect 306 with the laser light 109 to ablate the excess material defect 306. The defect shape 308-1 may indicate the topmost defect shape to be ablated and the defect shape 308-m may indicate the lowest defect shape to be ablated. The area of the defect shapes 308 may change with the ablation cycles due to area of the excess material defect 306 changing along the depth of the excess material defect. The area of the defect shapes 308 may increase as the defect shapes 308 get closer to the substrate 302. For example, the defect shape 308-m which is closer to the substrate 302 may include an area which is larger than the defect shape 308-1.

The repair system 100 may generate the laser light 109 and direct the laser light 109 to the excess material defect 306. For example, the repair system 100 may generate the laser light 109 in a plurality of pulses (depicted as dashes). The repair system 100 may ablate the excess material defect 306 at the current layer to which the laser light 109 is focused. For example, the current layer may be at the defect shape 308-m. The repair system 100 may ablate the shape of the defect shape 308-m from the excess material defect 306 with a plurality of pulses. The repair system 100 may then refocus the laser light 109 at the next layer (e.g., defect shape 308-(m−1)) and ablate the next layer. The repair system 100 may continue ablating and refocusing for the defect shape 308-m through defect shape 308-1. The laser light 109 may ablate the 3D shape of the excess material defect 306 determined from the 3D measurement 121. The excess material defect 306 may be ablated up to the 3D accuracy limit of the 3D measurement 121 with the residue remaining after the ablation. For example, the defect shape 308-1 may be disposed at the 3D accuracy limit of the 3D measurement 121. The residue of the defect may be below the defect shape 308-1 and below the 3D accuracy limit of the 3D measurement 121.

The repair system 100 may generate the 2D image 117. The 2D image 117 may include the residue of the excess material defect 306. The repair system 100 may ablate the residue of the excess material defect 306 based on the 2D image 117. The repair system 100 may iteratively generate the 2D image 117 and ablate the residue of the excess material defect 306 based on the 2D image 117 until the excess material defect 306 has been repaired. For example, in FIG. 3E the 2D image 117 may indicate the residue of the excess material defect 306 is below an allowable defect size such that the excess material defect 306 has been repaired.

Referring generally again to the figures. In embodiments, the controller 118 may be configured to change one or more optical properties of the illumination 103, illumination 103a, the laser light 109, and/or the collected light 119 based on feedback from the 2D image 117 from the detector 116. The controller 118 may change one or more components of the illumination path 105, the laser path 111, and/or the collection path 113 to change the optical properties of illumination 103, illumination 103a, the laser light 109, and/or the collected light 119. For example, the controller 118 may control the optical properties of the laser light 109 to change any of the spot size, fluence, waist position, beam profile, wavelength, Rayleigh length, and the like. The controller 118 may change the optical properties of the laser light 109 by vertically moving the objective lens 112, changing a zoom setting of the objective lens 112, changing the objective lens 112, varying a numerical aperture of the objective lens 112, varying a beam diameter of the laser light 109, changing a spot energy profile of the laser light 109, changing the wavelength of the laser light 109, or the like. Similarly, the controller 118 may control optical properties of the illumination 103, illumination 103a, and/or collected light 119 such as a field-of-view, focus, and the like. The controller 118 may change the optical properties of the illumination 103, illumination 103a, the laser light 109, and/or the collected light 119 during the repair of the defects.

In embodiments, the controller 118 may find the finest feature of the design of sample 115. The controller 118 may find the finest feature by a procedure such as computer aided manufacturing (CAM) learning. In embodiments, the controller 118 may be configured to change the optical properties of the laser light 109 according to the finest features of the sample 115. Although the controller 118 is described as setting the optical properties of the laser light 109 according to the finest features of the sample 115, this is not intended as a limitation of the present disclosure.

In embodiments, the controller 118 may change the optical properties of the laser light 109 during repair of defects of the sample 115. For example, the controller 118 may change the optical properties of the laser light 109 during repair of the sample 115 based on a size of the defect in the 2D image 117. By way of another example, the controller 118 may preset the optical properties of the laser light 109 based on an expected size of the defect according to the design resolution in the design file at the defect location 123.

In embodiments, the repair system 100 may configure one or more of the optical properties of the laser light 109 on a pulse-to-pulse basis. For example, the repair system 100 may configure energy, defocus, and/or diameter on a pulse-to-pulse basis. For instance, laser spots directed to impinge adjacent to “reference” conductors may have a different energy than laser spots directed to impinge farther from “reference” conductors. In embodiments, the repair system 100 may perform per-spot focusing. The repair system 100 may perform per-spot focusing by moving the objective lens 112, moving the sample 115, a variable-focus optical element, and the like. Configuring the optical properties on the pulse-by-pulse basis may include changing the properties every pulse, every other pulse, or a slower rate thereof.

In embodiments, the repair system 100 may configure one or more of the optical properties of the laser light 109 iteratively during repair of the defect. The repair system 100 may deliver the laser light 109 to the defect location 123. The fluence of the laser light 109 may be selected so that the laser light 109 does not damage the substrate of the sample 115, even if the laser light 109 does not fully remove the excess material upon the initial application of laser light 109 to the excess material. Following completion of an initial repair operation, the repair system 100 may acquire additional 2D image 117 of the defect location 123. For example, the repair system 100 may acquire the 2D image 117 of the defect location 123 after performing the ablations based on the 3D measurement 121. The repair system 100 may determine that some portion of the defect is still present at the defect location 123 based on the 2D image 117. For example, the repair system 100 may determine that the portion of the defect is present at the defect location 123 in the 2D image 117 (e.g., from a fluorescence image). The repair system 100 may adjust the optical properties of the laser light 109 and may deliver the laser light 109 to the defect location 123 using the adjusted optical properties. The adjusted optical properties may include reducing a fluence of the laser light 109. Reducing the fluence of the laser light 109 may be beneficial to reduce a likelihood of laser damage to the substrate 302. The process of verifying the presence of a defect, adjusting the optical properties, and automatically performing a repair operation may be repeated until the controller 118 determines that the defect has been repaired. The controller 118 may determine that the defect has been repaired by detecting that the defect is no longer present at the defect location in the 2D image 117 (e.g., from a fluorescence image). Upon determining that the defect has been repaired, the repair system 100 may reposition to a next of the defect locations 123.

Although much of the present disclosure is directed to repairing excess material defects, this is not intended as a limitation of the present disclosure. It is contemplated that the repair system 100 may also repair a missing material defect. The repair system 100 may include material dispensing hardware to repair the missing material defect. The material dispensing hardware may include chemical vapor deposition (CVD) hardware, solid or liquid dispensing hardware, laser-induced forward transfer (LIFT), ink-jet or other-directed material deposition systems. The repair system 100 may perform various repair operations. Repair operations include, for example, ablating spurious portions of conductors, removal of oxides formed on conductor portions, and/or processes to locally deposit additional conductor material or additional substrate material. Additional conductor material may be deposited and then irradiated by the laser light 109 to join the additional conductor material with the printed circuit. Although not depicted, the repair system may also include functionality for depositing a conductor portion at the defect location 123 where a part of a conductor is missing or malformed, and/or functionality for depositing a substrate portion at locations where a part of a substrate is missing or malformed. For example, the repair system may include an inkjet device.

The one or more processors may include any processor or processing element known in the art. For the purposes of the present disclosure, the term “processor” or “processing element” may be broadly defined to encompass any device having one or more processing or logic elements (e.g., one or more micro-processor devices, one or more application-specific integrated circuit (ASIC) devices, one or more field programmable gate arrays (FPGAs), or one or more digital signal processors (DSPs)). In this sense, the one or more processors may include any device configured to execute algorithms and/or instructions (e.g., program instructions stored in memory). In one embodiment, the one or more processors may be embodied as a desktop computer, mainframe computer system, workstation, image computer, parallel processor, networked computer, or any other computer system configured to execute a program. Moreover, different subsystems of the system may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers.

In embodiments, a controller may include one or more controllers housed in a common housing or within multiple housings. In this way, any controller or combination of controllers may be separately packaged as a module suitable for integration into a system. Further, the controllers may analyze data received from detectors and feed the data to additional components within the system or external to the system.

The memory may include any storage medium known in the art suitable for storing program instructions executable by the associated one or more processors. For example, the memory may include a non-transitory memory. By way of another example, the memory may include, but is not limited to, a read-only memory (ROM), a random-access memory (RAM), a magnetic or optical memory device (e.g., disk), a magnetic tape, a solid-state drive and the like. It is further noted that memory may be housed in a common controller housing with the one or more processors. In one embodiment, the memory may be located remotely with respect to the physical location of the one or more processors and controller. For instance, the one or more processors of controller may access a remote memory (e.g., server), accessible through a network (e.g., internet, intranet and the like).

As used throughout the present disclosure, the term “sample” generally refers to a substrate formed of a semiconductor or non-semiconductor material (e.g., thin filmed glass, ceramic, organic laminate, or the like). For example, a semiconductor or non-semiconductor material may include, but is not limited to, monocrystalline silicon, gallium arsenide, indium phosphide, organic substrate such as Ajinomoto Build-up film (ABF), or a glass material. A sample may include one or more layers. For example, such layers may include, but are not limited to, a resist (including a photoresist), a dielectric material, a conductive material, and a semiconductive material. Many different types of such layers are known in the art, and the term sample as used herein is intended to encompass a sample on which all types of such layers may be formed. One or more layers formed on a sample may be patterned or un-patterned. For example, a sample may include a plurality of dies, each having repeatable patterned features. Formation and processing of such layers of material may ultimately result in completed devices. Many different types of devices may be formed on a sample, and the term sample as used herein is intended to encompass a sample on which any type of device known in the art is being fabricated. Further, for the purposes of the present disclosure, the term sample, panel, and wafer should be interpreted as interchangeable. In addition, for the purposes of the present disclosure, the terms patterning device, mask and reticle should be interpreted as interchangeable.

It is further contemplated that each of the embodiments of the methods described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mixable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

1. A repair system comprising:
a light source configured to generate illumination;
a laser generator configured to generate laser light;
a two-axis scanner configured to steer the laser light;
a sample stage configured to support a sample;
an objective lens, wherein the laser light is configured to pass through the objective lens to the sample to perform a repair of a defect located at a defect location on the sample;
a detector configured to generate a 2D image of the defect location based on collected light, wherein the collected light reflects or is emitted from the defect location, through the objective lens, to the detector; and
a controller comprising one or more processors configured to execute program instructions maintained on a memory, the program instructions causing the controller to:
generate a 3D measurement of the defect location;
determine a 3D shape of the defect by comparing the 3D measurement with an expected design of the defect location;
ablate the 3D shape of the defect by iteratively:
ablating a defect shape of the defect in a current layer by scanning the laser light at the defect shape;
generate the 2D image;
find a residue of the defect in the 2D image; and
ablate the residue of the defect.

2. The repair system of claim 1, wherein the 3D measurement is generated using depth from focus.

3. The repair system of claim 2, wherein the detector is configured to generate a plurality of 2D images with a plurality of inter-image shifts in a focal plane; wherein the 3D measurement is generated from the plurality of 2D images.

4. The repair system of claim 3, wherein the plurality of inter-image shifts in the focal plane decrease towards a substrate of the sample.

5. The repair system of claim 1, comprising a 3D camera; wherein the controller is configured to cause the 3D camera to generate the 3D measurement.

6. The repair system of claim 1, wherein the program instructions cause the controller to segment the 3D shape into a plurality of defect shapes which are stacked together.

7. The repair system of claim 1, wherein the program instructions cause the controller to determine the 3D shape has been ablated using an open loop condition.

8. The repair system of claim 7, wherein the open loop condition is a depth ablated at the current layer estimated by the controller using a fluence of the laser light.

9. The repair system of claim 7, wherein the repair system ablates the 3D shape without generating an additional 3D measurement.

10. The repair system of claim 1, wherein the residue of the defect is below a 3D accuracy limit of the 3D measurement.

11. The repair system of claim 1, wherein the program instructions cause the controller to iteratively generate the 2D image of the defect location, find the residue of the defect, and ablate the residue of the defect.

12. The repair system of claim 11, wherein the program instructions cause the controller to iteratively generate the 2D image of the defect location, find the residue of the defect, and ablate the residue of the defect until the controller determines the residue of the defect is below an allowable defect size.

13. The repair system of claim 11, wherein the program instructions cause the controller to refocus the laser light at a different depth when iteratively generating the 2D image of the defect location, finding the residue of the defect, and ablating the residue of the defect.

14. The repair system of claim 1, wherein the defect is an excess material defect; wherein the laser light repairs the excess material defect by ablating the excess material defect.

15. The repair system of claim 1, wherein the memory maintains a design file and a defect report, wherein the design file comprises the expected design.

16. The repair system of claim 1, wherein the collected light reflecting from the sample comprises light emitted by the sample following excitation by at least one of the illumination or the laser light.

17. The repair system of claim 1, wherein the illumination is directed to the sample in a brightfield configuration; wherein the illumination and the laser light are configured to pass through the objective lens to the sample.

18. The repair system of claim 1, wherein the illumination is directed to the sample in a darkfield configuration.

19. The repair system of claim 1, wherein the controller is configured to ablate the 3D shape of the defect by iteratively:
ablating the defect shape of the defect in the current layer by scanning the laser light at the defect shape; and
refocusing the laser light down to a next layer.

20. The repair system of claim 19, wherein the controller is configured to ablate the defect shape of the defect in the current layer by scanning the laser light at the defect shape one time before refocusing the laser light down to the next layer.

21. The repair system of claim 19, wherein the controller is configured to ablate the defect shape of the defect in the current layer by scanning the laser light at the defect shape a plurality of times before refocusing the laser light down to the next layer.

22. The repair system of claim 1, wherein the controller is configured to ablate the defect shape of the defect in the current layer by scanning the laser light at the defect shape a plurality of times without refocusing the laser light down to a next layer.

23. The repair system of claim 1, wherein the controller is configured to:
generate an additional 3D measurement of the defect location, wherein the additional 3D measurement indicates the defect remains at the defect location;
determine the 3D shape of the defect from the additional 3D measurement; and
ablate the 3D shape of the defect.

24. A method comprising:
generating a 3D measurement of a defect location, wherein a defect is located at the defect location on a sample;
determining a 3D shape of the defect by comparing the 3D measurement with an expected design of the defect location;
ablating the 3D shape of the defect by iteratively:
ablating a defect shape of the defect in a current layer by scanning a laser light at the defect shape;
generating a 2D image;
finding a residue of the defect in the 2D image; and
ablating the residue of the defect.
